(19) United States
(12) Patent Application Publication
(10) Pub. No.: US 2024/0224457 A1
(43) Pub. Date: Jul. 4, 2024

(54) SWITCHING POWER SUPPLY DEVICE AND POWER CONVERSION DEVICE

(71) Applicant: Panasonic Automotive Systems Co., Ltd., Kanagawa (JP)

(72) Inventor: Ryota HOSAKA, Tokyo (JP)

(21) Appl. No.: 18/602,775

(22) Filed: Mar. 12, 2024

Related U.S. Application Data
(63) Continuation of application No. PCT/JP2022/018468, filed on Apr. 21, 2022.

(30) Foreign Application Priority Data
Sep. 21, 2021 (JP) 2021-153424

(51) Int. Cl. H05K 7/14; H02M 3/00; H05K 7/20

(52) U.S. Cl. CPC H05K 7/14322; H02M 3/003; H05K 7/20272

(57) ABSTRACT

A switching power supply device according to the present disclosure includes: a first circuit board; a second circuit board; and a housing that accommodates the first circuit board and the second circuit board. A part of the housing is a barrier that separates the first circuit board and the second circuit board.

### CROSS-REFERENCE TO RELATED APPLICATIONS

This application is a continuation of International Application No. PCT/JP2022/018468, filed on Apr. 21, 2022 which claims the benefit of priority of the prior Japanese Patent Application No. 2021-153424, filed on Sep. 21, 2021, the entire contents of which are incorporated herein by reference.

### FIELD

Embodiments described herein relate generally to a switching power supply device and a power conversion device.

### BACKGROUND

In recent years, vehicles such as hybrid cars and electric cars with batteries are becoming widespread. The vehicle is equipped with devices such as: a charging device that charges a battery mounted on the vehicle from an external battery or an external power source; a power conversion device including an inverter etc. that converts a direct current from the battery into an alternating current; and a motor that rotates wheels or the like of the vehicle by the converted alternating current. In order to spread vehicles equipped with batteries in the future, there is further needed, for example, the achievement of lower vehicle prices and an extended distance to empty.

The devices such as the charging device and the power conversion device described above have a configuration including a circuit board using a power semiconductor as a component, in which the circuit board is accommodated in a metal housing. In order to achieve stable supply power, the device needs to reduce noise generated in the circuit board.

To handle this, there is a noise reduction technique in which a circuit board including a circuit that generates noise and a circuit board including a circuit that removes the generated noise are separately provided and are accommodated in a housing formed of a cast. At this time, individual circuit boards are accommodated in the housing separately in different sections by separate metal components. Conventionally, there has been proposed a technique of shielding mutual interference of noise by using a shield formed of separate metal component (e.g., see JP 2005-287273 A).

However, in the above-described conventional technique, the shield is formed of a separate component, which leads to an increase in the number of components of the device and an increase in size and weight of the entire device. In addition, a configuration using separate components will cause a problem of an increased cost or the like regarding the corresponding components. Furthermore, for example, a configuration using the shield as a welded separate component would need a cost for welding.

On the other hand, using separate metal casts for the housing and the shield in order to improve a shielding effect leads to a further increase in size and weight of the entire device, causing a further increase in the cost for producing the casts. With this configuration, an increase in the number of components of the device and an increase in the size and weight of the entire device affect the price of the vehicle on which the device is mounted as well as the cruising distance of the vehicle. In order to solve these problems, there is a need to improve the configuration and shape of the shield.

### SUMMARY

A switching power supply device according to an embodiment of the present disclosure includes: a first circuit board; a second circuit board; and a housing that accommodates the first circuit board and the second circuit board. A part of the housing is a barrier that separates the first circuit board and the second circuit board.

### BRIEF DESCRIPTION OF THE DRAWINGS

FIG. 1 is a block diagram schematically illustrating an example of a configuration of a switching power supply device according to a first embodiment;

FIG. 2 is a cross-sectional view schematically illustrating an example of a cross section of the switching power supply device according to the first embodiment;

FIG. 3 is a cross-sectional view schematically illustrating, as a comparative example, an example of a cross section in a case where a shield of a second circuit board is formed of a separate processed metal in a conventional switching power supply device;

FIG. 4 is a cross-sectional view schematically illustrating, as a comparative example, an example of a cross section in a case where the shield of the second circuit board is formed of a separate cast member in the conventional switching power supply device; and

FIG. 5 is a block diagram schematically illustrating an example of a configuration of a power conversion device according to a second embodiment.

### DETAILED DESCRIPTION

### First Embodiment

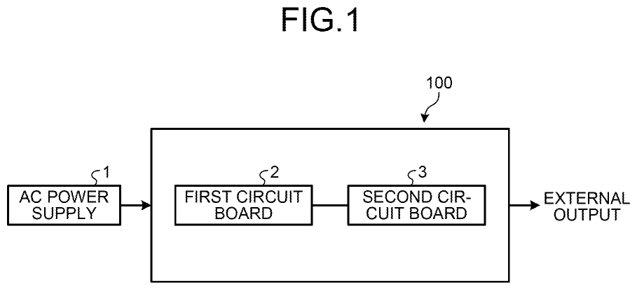

Hereinafter, a specific description will be given with reference to the accompanying drawings. FIG. 1 is a block diagram schematically illustrating an example of a configuration of a switching power supply device. A switching power supply device 100 is a device that converts AC power from an AC power supply 1 into DC power and outputs the obtained DC power to an outside. The AC power supply 1 is not limited to a single-phase AC power supply, and may be a two-phase AC power supply or a three-phase AC power supply.

The first circuit board 2 has a circuit that generates noise. The first circuit board 2 outputs the AC power input from the second circuit board 3 to an outside. For example, the first circuit board 2 includes a rectifier circuit, a power factor correction circuit, a capacitor, and the like (which are not illustrated). The configuration and function of the first circuit board 2 are not limited thereto. In addition, hereinafter, the first circuit board 2 is also simply referred to as a first circuit 2.

The rectifier circuit applies full-wave rectification on the AC power, input from the second circuit board 3, to be converted into DC power, and outputs the obtained DC power to the power factor correction circuit. For example, the rectifier circuit is a diode bridge circuit.

The power factor correction circuit is a circuit having a function of improving a power factor of power input from the rectifier circuit and boosting a voltage of the input power.

The capacitor is connected to an output side of the power factor correction circuit, and smooths DC power input by the power factor correction circuit. Thereafter, the smoothed DC power is output to an outside. Since the voltage of the DC power is boosted by the power factor correction circuit, the capacitor has a relatively large capacity such as an electrolytic capacitor.

The second circuit board 3 has a circuit that removes noise generated in the first circuit board 2. The second circuit board 3 outputs the AC power input from the AC power supply 1 to the first circuit board 2. More specifically, the second circuit board 3 removes noise generated in the first circuit 2 so as not to be transmitted to the AC power supply 1. In addition, the second circuit board 3 reduces noise entering from the AC power supply 1. The configuration and function of the second circuit board 3 are not limited thereto. In the following description, the second circuit board 3 is also simply referred to as a second circuit 3.

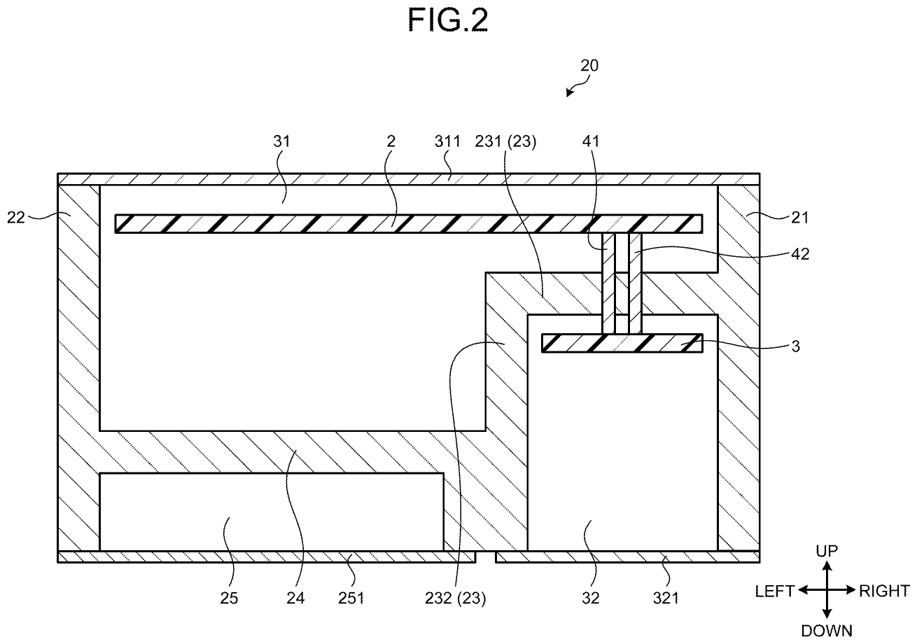

FIG. 2 is a cross-sectional view schematically illustrating an example of a cross section of the switching power supply device 100 according to the first embodiment. The switching power supply device 100 according to the present embodiment includes the first circuit board 2, the second circuit board 3, and a housing 20 that accommodates the first circuit board 2 and the second circuit board 3.

In the present embodiment, the switching power supply device 100 has a configuration in which the first circuit board 2 and the second circuit board 3 are formed as separate boards. In the present embodiment, the housing 20 is a cast product formed by a casting method, and has heat resistance and rigidity. The housing 20 is formed by aluminum casting, for example.

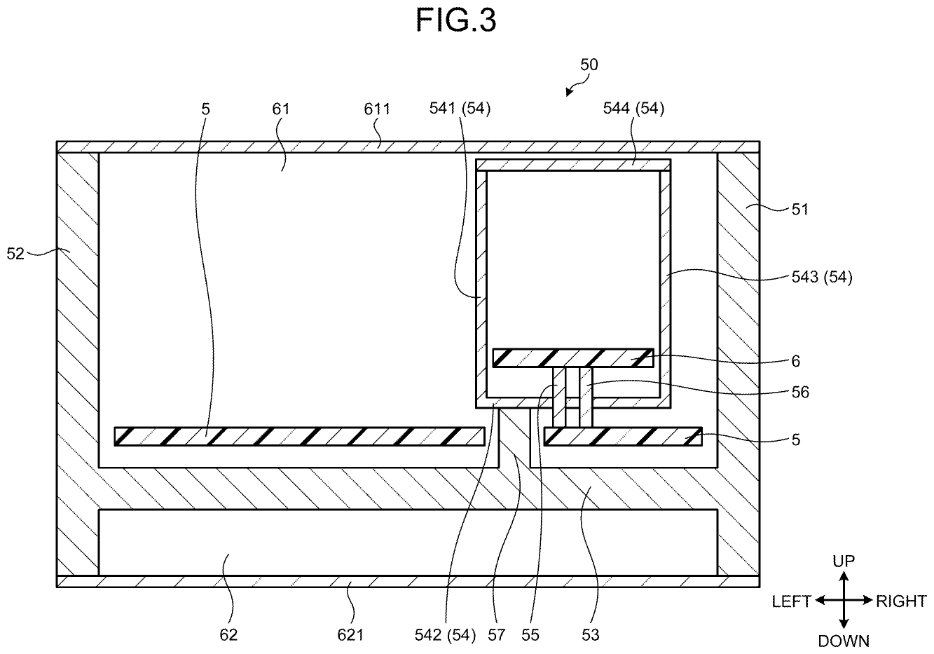

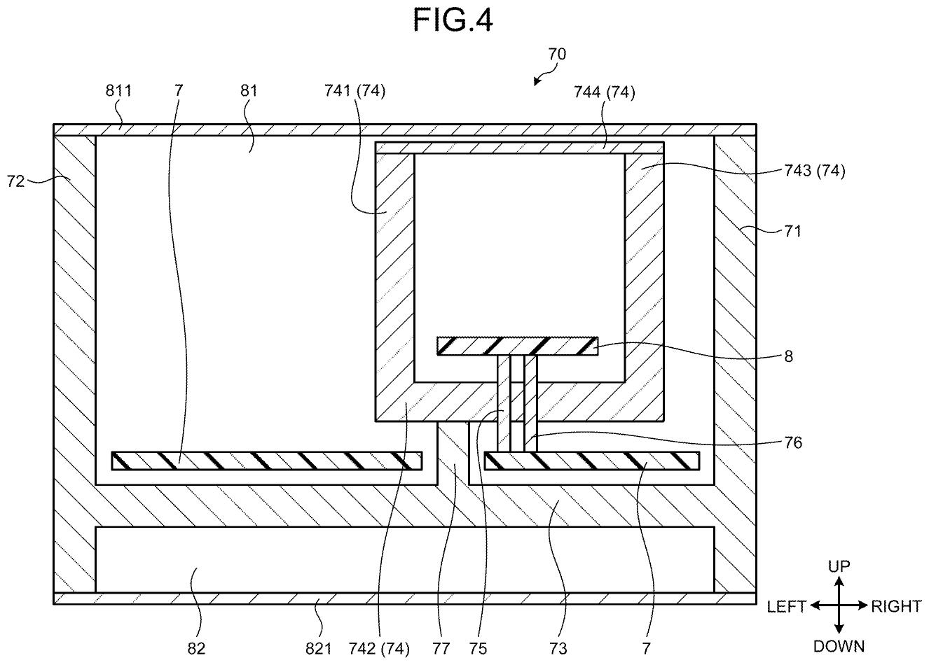

In the present specification, a direction toward the left side surface of the housing 20 is defined as a left direction, while a direction toward the right side surface is defined as a right direction. A direction toward the upper side of the housing is defined as an upward direction, and a direction toward the lower side is defined as a downward direction. Hereinafter, the similar applies to FIGS. 3 and 4.

Next, a configuration of the housing 20 will be described. The housing 20 is a hollow housing. The housing 20 includes at least a first side wall 21 and a second side wall 22. In addition, the housing 20 has barriers (a first barrier 23 and a second barrier 24) integrally formed with the housing 20 so as to separate a space accommodating the first circuit board 2 and the second circuit board 3. The housing 20 divides a space in the housing 20 into upper and lower spaces by the barriers.

Within the housing 20, an upper space separated by the barrier includes a first accommodating portion 31 for accommodating the first circuit board 2. The first accommodating portion 31 is formed of a part of the first side wall 21, a part of the second side wall 22, the first barrier 23, and the second barrier 24.

In addition, within the housing 20, a lower space separated by the barrier includes a second accommodating portion 32 and a cooling passage 25. The second accommodating portion 32 is an accommodating portion for accommodating the second circuit board 3. The second accommodating portion 32 is formed by the first barrier 23 and a part of the first side wall 21.

The cooling passage 25 is formed by a part of the second side wall 22, a second portion 232 being a part of the first barrier 23, and the second barrier 24. In the present embodiment, the cooling passage 25 is a passage that accommodates a cooling device that uses a liquid cooling method for cooling using a refrigerant such as water, for example.

In addition, the cooling passage 25 cools the first accommodating portion 31 via the second barrier 24. The second barrier 24 is joined with the first barrier 23. Therefore, the heat of the second accommodating portion 32 that accommodates the second circuit board 3 is conducted to the second barrier 24 via the first barrier 23. This makes it possible for the cooling passage 25 to cool the entire interior of the housing including the first accommodating portion 31 and the second accommodating portion 32 within the housing 20.

The housing 20 further includes upper and lower lid members. The upper and lower lid members are processed metals, for example. More specifically, the housing 20 includes, on top of the housing 20, a first lid member 311 for covering the first accommodating portion 31. In addition, the housing 20 includes, at a bottom of the housing 20, a second lid member 321 for covering the second accommodating portion 32 and a third lid member 251 for covering the cooling passage 25. Materials of the upper and lower lid members are not limited to processed metal.

Next, the barrier will be described. The barrier includes the first barrier 23 covering the second circuit board 3 and the second barrier 24 extending from the first barrier 23 in the left direction in the drawing. The first barrier 23 separates the first circuit board 2 (first accommodating portion 31) and the second circuit board 3 (second accommodating portion 32). The second barrier 24 separates the first circuit board 2 (first accommodating portion 31) and the cooling passage 25 that cools the first circuit board 2.

The first barrier 23 is a part of the housing 20, and is integrally formed with the housing 20. The first barrier 23 includes: a part of the first side wall 21; a first portion 231 extending from the first side wall 21 toward the second side wall 22 of the housing 20; and the second portion 232 extending from an end of the first portion 231 toward the lower side of the housing 20. The first portion 231 separates the first circuit board 2 and the second circuit board 3. The second portion 232 separates the first circuit board 2, the second circuit board 3, and the cooling passage 25.

The second barrier 24 is a part of the housing 20, and is integrally formed with the housing 20. The second barrier 24 extends leftward from the second portion 232 toward the second side wall 22. The second barrier 24 separates the first circuit board 2 and the cooling passage 25.

Next, a connection relationship between the first circuit board 2 and the second circuit board 3 will be described. The first circuit board 2 and the second circuit board 3 are connected by a metal connection member. For example, the connection members include a first connection member 41 and a second connection member 42. The first connection member 41 and the second connection member 42 output the AC power output from the second circuit 3 to the first circuit 2.

The first circuit board 2 and the second circuit board 3 are disposed at adjacent positions via the first connection member 41 and the second connection member 42. This makes it possible for the switching power supply device 100 to output the AC power output from the second circuit 3 to the first circuit 2 through a short path, leading to downsizing of the switching power supply device 100. The number and arrangement of the first connection member 41 and the second connection member 42 are not limited thereto.

As described above, the switching power supply device 100 according to the present embodiment includes the first circuit board 2, the second circuit board 3, and the housing 20 that accommodates the first circuit board 2 and the second circuit board 3. Moreover, a part of the housing 20 forms a barrier that separates the first circuit board 2 and the second circuit board 3.

According to the configuration of the present embodiment described above, a part of the housing 20 is a barrier that separates the first circuit board 2 and the second circuit board 3, making it possible to cover the second circuit board 3. With this configuration, the barrier becomes a shield of the second circuit board 3, and the shield is integrally formed with the housing 20. This eliminates the need to provide a separate shield, making it possible to achieve downsizing of the entire housing 20 accommodating the circuit board. In addition, since a separate shield is unnecessary, the entire switching power supply device 100 can be reduced in weight. Furthermore, integrally forming the shields makes it possible to reduce the number of shields and components such as screws for fastening the shields to the housing, and eliminate the need to provide a separate shielding mold, leading to reduction of the cost of the entire switching power supply device 100.

### Description of Conventional Switching Power Supply Device

Next, an operation of the housing 20 of the present embodiment will be described with reference to FIG. 3. FIG. 3 is a cross-sectional view schematically illustrating an example of a cross section in a case where a shield of the first circuit board is formed of a separate processed metal in a conventional switching power supply device. Description common to the above-described first embodiment will be omitted as appropriate. In the first embodiment described above, the first circuit board and the second circuit board are accommodated in the same housing. In contrast, the conventional switching power supply device in FIG. 3 is different from the above-described first embodiment in that a first circuit board, a second circuit board, and another housing that accommodates the second circuit board, are accommodated in the same housing.

First, a configuration of a conventional housing will be described. A housing 50 includes a first side wall 51, a second side wall 52, and a separating portion 53 that separates an accommodating portion 61 and a cooling passage 62. A housing 54, provided as a separate part, shields a second circuit board 6 and serves as a shield. The housing 54 is formed of a first barrier 541, a second barrier 542, a third barrier 543, and a fourth barrier 544. The second barrier 542 is disposed between a first circuit board 5 and the second circuit board 6. The fourth barrier 544 is a lid member that covers the upper portion of the housing 54.

An upper space in the housing 50 separated by the separating portion 53 is provided with the accommodating portion 61 for accommodating the first circuit board 5, the second circuit board 6, and the housing 54. The accommodating portion 61 is formed by a part of the first side wall 51, a part of the second side wall 52, and the separating portion 53.

Within the housing 50, a lower space separated by the separating portion 53 includes the cooling passage 62. The housing 50 includes upper and lower lid members. More specifically, the upper portion of the housing 50 includes a first lid member 611 for covering the accommodating portion 61, while the lower portion of the housing 50 includes a second lid member 621 for covering the cooling passage 62.

The cooling passage 62 cools the accommodating portion 61 via the separating portion 53. A first connection member 55 and a second connection member 56 are metal connection members that output AC power output from the second circuit 6 to the first circuit 5. In addition, a support portion 57 illustrated in FIG. 3 is a portion that supports the housing 54 from the separating portion 53 of the accommodating portion 61, and is also a ground making a reference potential of the circuit operation. The first circuit board 5 needs to be formed avoiding the support portion 57, and thus, a part of the first circuit board 5 is cut out so as to avoid the support portion 57, or the first circuit board 5 is penetrated. Therefore, the mountable area of the first circuit board 5 is inevitably reduced by an amount of avoiding the support portion 57.

In comparison of the housing 50 illustrated in FIG. 3 and the housing 20 illustrated in FIG. 2, the housing 50 accommodates the separate housing 54, whereas the housing 20 accommodates no separate housing. In the present embodiment, a part of the housing 20 includes the first barrier 23 and includes no shield formed of a separate housing, achieving downsizing of the housing 20. Since there is no shield formed of a separate housing, it is possible to reduce the number of components of the switching power supply device 100. Moreover, this configuration makes it possible to lower the vertical direction of the side walls of the housing, enabling reduction of the height of the switching power supply device 100. For example, when the switching power supply device 100 is mounted on the vehicle, the switching power supply device 100, which can be downsized and lowered in height, has an increased degree of freedom when being mounted on the vehicle.

In addition, the separate housing 54 formed of processed metal illustrated in FIG. 3 is a shield formed of processed metal, and thus, there might be a gap produced by bending or the like. Regarding the case of occurrence of a gap, welding is to be performed on the entire circumference of the shield so as prevent the occurrence of the gap. In this regard, the present embodiment has a configuration in which the second circuit board 3 is shielded by the barrier formed integrally with the housing 20. This configuration eliminates the need of performing welding, achieving reduced cost, as compared with a shield formed as a separate body.

In addition, in comparison of the cooling passage 25 of the present embodiment illustrated in FIG. 2 and the conventional cooling passage 62 illustrated in FIG. 3, the conventional cooling passage 62 cools the accommodating portion 61. In contrast, the cooling passage 25 of the present embodiment can cool the entire interior of the housing including the first accommodating portion 31 and the second accommodating portion 32. This increases the cooling efficiency, making it possible, as compared with the conventional case, to achieve a downsized cooling passage and an increased degree of freedom in designing the housing.

In the present embodiment, in comparison of the first barrier 23 illustrated in FIG. 2 and the housing 54 illustrated in FIG. 3, there is a need, in FIG. 3, to support the housing 54 in the accommodating portion 61 by the support portion 57 in order to accommodate the housing 54 in the accommodating portion 61 of the housing 50. In addition, in the configuration of FIG. 3, the support portion 57 is necessary to perform reinforcement of the ground of the housing 54. In contrast, the present embodiment uses the configuration illustrated in FIG. 2, in which the first barrier 23 that covers the second circuit board 3 is included in a part of the housing 20, with no shielding formed of a separate housing. With this configuration, there is no need to support the shielding inside the housing, or the need to reinforce the ground. This makes it possible for the present embodiment to have a configuration that needs no support portion, leading to downsizing of the entire switching power supply device 100.

In addition, the configuration of the present embodiment illustrated in FIG. 2 needs no separate housing 54. This makes it possible to reduce the weight of the switching power supply device 100 as well as reduce the cost of the entire switching power supply device 100. Furthermore, the configuration of the present embodiment illustrated in FIG. 2 includes no support portion 57, eliminating the need to locate the first circuit board 2 avoiding the support portion 57, leading to maximum possible usage of the mountable area. This makes it possible to downsize the first circuit board 2.

The operation of the housing 20 of the present embodiment will be described with reference to FIG. 4. FIG. 4 is a cross-sectional view schematically illustrating an example of a cross section in a case where the shield of the first circuit board is formed of a separate cast member in the conventional switching power supply device. Description common to the above-described first embodiment will be omitted as appropriate. In the first embodiment described above, the first circuit board and the second circuit board are accommodated in the same housing. In contrast, the conventional switching power supply device in FIG. 4 is different from the above-described first embodiment in that a first circuit board, a second circuit board, and another housing that accommodates the second circuit board, are accommodated in the same housing.

The conventional switching power supply devices of FIGS. 3 and 4 are different from each other in that the housing that accommodates the first circuit board is formed of processed metal in the case of FIG. 3, whereas the housing that accommodates the second circuit board is a cast member in the case of FIG. 4.

First, a configuration of a conventional housing will be described. A housing 70 includes a first side wall 71, a second side wall 72, and a separating portion 73 that separates an accommodating portion 81 and a cooling passage 82. A housing 74, provided as a separate part, shields a second circuit board 8 and serves as a shield. The separate housing 74 is formed of a first barrier 741, a second barrier 742, a third barrier 743, and a fourth barrier 744. The second barrier 742 is disposed between the first circuit board 7 and the second circuit board 8. The fourth barrier 744 is a lid member that covers the upper portion of the housing 74.

Within the housing 70, an upper space separated by the separating portion 73 includes the accommodating portion 81 for accommodating the first circuit board 7, the second circuit board 8, and the housing 74. The accommodating portion 81 is formed of a part of the first side wall 71, a part of the second side wall 72, and the separating portion 73.

Within the housing 70, a lower space separated by the separating portion 73 includes the cooling passage 82. The housing 70 includes upper and lower lid members. More specifically, the upper portion of the housing 70 includes a first lid member 811 for covering the accommodating portion 81, and the lower portion of the housing 70 includes a second lid member 821 for covering the cooling passage 82.

The cooling passage 82 cools the accommodating portion 81 via the separating portion 73. A first connection member 75 and a second connection member 76 are metal connection members that output AC power output from the second circuit 8 to the first circuit 7. In addition, a support portion 77 illustrated in FIG. 4 is a portion that supports the housing 74 from the separating portion 73 of the accommodating portion 81, and is also a ground making a reference potential of the circuit operation. The first circuit board 7 needs to be formed avoiding the support portion 77, similarly to the configuration of FIG. 3, and thus, a part of the first circuit board 7 is cut out so as to avoid the support portion 77, or the first circuit board 7 is penetrated. Therefore, the mountable area of the first circuit board 7 is inevitably reduced by an amount of avoiding the support portion 77.

In the present embodiment, in comparison of the first barrier 23 illustrated in FIG. 2 and the housing 74 including the cast member illustrated in FIG. 4, it is necessary, in FIG. 4, to support the housing 74 at the accommodating portion 81 by the support portion 77 in order to accommodate the housing 74 in the accommodating portion 81 of the housing 70. In addition, in the configuration of FIG. 4, the support portion 77 is necessary to enforce the ground of the housing 74. In contrast, the present embodiment uses the configuration illustrated in FIG. 2, in which the first barrier 23 that covers the second circuit board 3 is included in a part of the housing 20, with no shielding formed of a separate housing. With this configuration, there is no need to support the shielding inside the housing, or the need to reinforce the ground. This makes it possible for the present embodiment to have a configuration that needs no support portion, leading to downsizing of the entire switching power supply device 100.

Furthermore, the configuration of the present embodiment illustrated in FIG. 2 needs no separate housing 74 formed of a cast member, making it possible to dramatically reduce the weight of the switching power supply device 100. In addition, the configuration of the present embodiment illustrated in FIG. 2 needs no separate housing 74. This eliminates the need to provide a mold for casting the separate housing 74, making is possible to dramatically reduce the cost of entire switching power supply device 100. Furthermore, the configuration of the present embodiment illustrated in FIG. 2 includes no support portion 77, eliminating the need to locate the first circuit board 2 avoiding the support portion 77, leading to maximum possible usage of the mountable area. This makes it possible to downsize the first circuit board 2.

### Second Embodiment

A second embodiment will be described. Description common to the above-described first embodiment will be omitted as appropriate. In the first embodiment described above, the configuration includes the first circuit board 2, the second circuit board 3, and the housing 20 that accommodates the first circuit board 2 and the second circuit board 3, in which a part of the housing 20 is a barrier that separates the first circuit board 2 and the second circuit board 3.

In contrast, the present embodiment is different from the above-described first embodiment in that: the first embodiment includes the first circuit board 2, the second circuit board 3, and the housing 20 that accommodates the first circuit board 2 and the second circuit board 3; the first circuit board 2 includes a voltage conversion circuit that performs a conversion into a voltage that is capable of being output to an outside; and a part of the housing 20 is a barrier that separates the first circuit board 2 and the second circuit board 3.

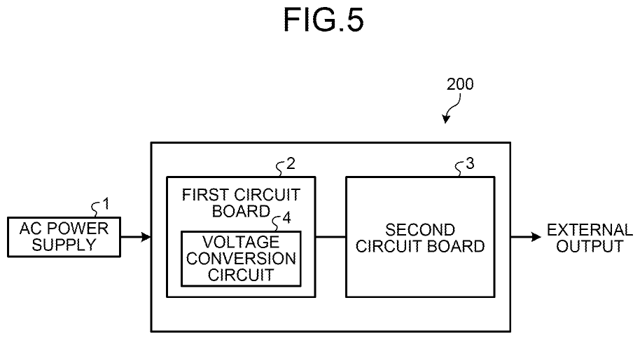

A power conversion device 200 according to a second embodiment will be described with reference to FIG. 5. FIG. 5 is a block diagram schematically illustrating an example of a configuration of the power conversion device 200.

The first circuit board 2 has a circuit that generates noise and has a circuit including the voltage conversion circuit 4. The voltage conversion circuit 4 is a circuit that performs a conversion into a voltage that is capable of being output to an outside, and includes a DC/DC converter (not illustrated), for example. The configuration and function of the voltage conversion circuit 4 are not limited thereto.

The DC/DC converter is a circuit that converts a DC output from the power factor correction circuit into a voltage that can be output to an outside. The DC/DC converter includes a power conversion circuit, a transformer, and a rectifier (none of which are illustrated).

The power conversion circuit is a circuit that converts DC power input by the power factor correction circuit into AC power. The transformer outputs the AC power input from the power conversion circuit to the rectifier. The rectifier rectifies the AC power input by the transformer into DC power. The rectifier outputs the rectified DC power to an outside.

The voltage conversion circuit 4 of the power conversion device 200 according to the present embodiment is not limited to a DC/DC converter, and may include an AC/DC converter, a DC/AC converter, a combination thereof, or the like, so as to be applicable to various power electronics.

As described above, the power conversion device 200 according to the present embodiment includes the first circuit board 2, the second circuit board 3, and the housing 20 that accommodates the first circuit board 2 and the second circuit board 3. The first circuit board 2 includes the voltage conversion circuit 4 that performs a conversion into a voltage that is capable of being output to an outside. A part of the housing 20 is a barrier that separates the first circuit board 2 and the second circuit board 3.

According to the configuration of the present embodiment described above, a part of the housing 20 is a barrier that separates the first circuit board 2 and the second circuit board 3, making it possible to cover the second circuit board 3. With this configuration, the barrier becomes a shield of the second circuit board 3, and the shield is integrally formed with the housing 20. This eliminates the need to provide a separate shield, making it possible to achieve downsizing of the entire housing 20 accommodating the circuit board. In addition, since a separate shield is unnecessary, the entire power conversion device 200 can be reduced in weight. Furthermore, integrally forming the shields makes it possible to reduce the number of shields and components such as screws for fastening the shields to the housing, and eliminate the need to provide a separate shielding mold, leading to reduction of the cost of the entire power conversion device 200.

### First Modification

In the present embodiment, the housing 20 is provided as a cast product formed by a casting method. An aluminum die-cast is used as a material of the housing. However, the material is not limited thereto, and may be another material.

### Second Modification

In the present embodiment, the cooling passage 25 accommodates a device that performs cooling by a liquid cooling method using a refrigerant such as water, but may accommodate a device that performs cooling by an air cooling method. The technology according to the present disclosure can also be implemented by accommodating a cooling device of an air cooling type or a heat sink type in the cooling passage 25.

The present disclosure provides a switching power supply device and a power conversion device capable of reducing the size, weight, and cost of a housing that accommodates a circuit board.

In the switching power supply device according to the present disclosure, a part of the housing is integrally formed with a barrier that separates the first circuit board and the second circuit board. The barrier serves as a shield of the first circuit board, leading to elimination of the need to provide a separate shield, enabling downsizing of the housing that accommodates the circuit.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A switching power supply device comprising:
a first circuit board;
a second circuit board; and
a housing that accommodates the first circuit board and the second circuit board, wherein
a part of the housing is a barrier that separates the first circuit board and the second circuit board.

2. The switching power supply device according to claim 1, wherein
the barrier includes:
a first barrier that covers the second circuit board; and
a second barrier that extends from the first barrier, and
the second barrier separates the first circuit board and a cooling passage that cools the first circuit board.

3. The switching power supply device according to claim 1, wherein
the housing includes a cast product formed by a casting method.

4. The switching power supply device according to claim 2, wherein
the housing includes a cast product formed by a casting method.

5. The switching power supply device according to claim 1, wherein
the first circuit board includes a circuit that generates noise, and
the second circuit board includes a circuit that removes the noise generated by the first circuit board.

6. The switching power supply device according to claim 2, wherein
the first circuit board includes a circuit that generates noise, and
the second circuit board includes a circuit that removes the noise generated by the first circuit board.

7. The switching power supply device according to claim 3, wherein
the first circuit board includes a circuit that generates noise, and
the second circuit board includes a circuit that removes the noise generated by the first circuit board.

8. The switching power supply device according to claim 4, wherein
the first circuit board includes a circuit that generates noise, and
the second circuit board includes a circuit that removes the noise generated by the first circuit board.

9. A power conversion device comprising:
a first circuit board;
a second circuit board; and
a housing that accommodates the first circuit board and the second circuit board, wherein
the first circuit board includes a voltage conversion circuit that performs a conversion into a voltage that is capable of being output to an outside, and
a part of the housing is a barrier that separates the first circuit board and the second circuit board.

10. The power conversion device according to claim 9, wherein
the barrier includes:
a first barrier that covers the second circuit board; and
a second barrier that extends from the first barrier, and
the second barrier separates the first circuit board and a cooling passage that cools the first circuit board.

11. The power conversion device according to claim 9, wherein
the housing includes a cast product formed by a casting method.

12. The power conversion device according to claim 10, wherein
the housing includes a cast product formed by a casting method.

13. The power conversion device according to claim 9, wherein
the first circuit board includes a circuit that generates noise, and
the second circuit board includes a circuit that removes the noise generated by the first circuit board.

14. The power conversion device according to claim 10, wherein
the first circuit board includes a circuit that generates noise, and
the second circuit board includes a circuit that removes the noise generated by the first circuit board.

15. The power conversion device according to claim 11, wherein
the first circuit board includes a circuit that generates noise, and
the second circuit board includes a circuit that removes the noise generated by the first circuit board.

16. The power conversion device according to claim 12, wherein
the first circuit board includes a circuit that generates noise, and
the second circuit board includes a circuit that removes the noise generated by the first circuit board.
